(19) United States
(12) Patent Application Publication
(10) Pub. No.: US 2006/0057818 A1
(43) Pub. Date: Mar. 16, 2006

(54) Package structure and method for optoelectric products

(75) Inventor: Chih-Lung Chen, Fongshan City (TW)

Correspondence Address: BACON & THOMAS, PLLC, 625 SLATERS LANE, FOURTH FLOOR, ALEXANDRIA, VA, 22314, US

(73) Assignee: Advanced Semiconductor Engineering, Inc., Kaohsiung (TW)

(21) Appl. No.: 11/221,813

(22) Filed: Sep. 9, 2005

(30) Foreign Application Priority Data
Sep. 10, 2004 (TW) 93127558

(51) Int. Cl. H01L 21/30; H01L 21/44

(52) U.S. Cl. 438/455; 438/613

(57) ABSTRACT

An optoelectric product is packaged according to the technology of wafer level chip scale package. A transparent wafer with multitudes of cavities is bonded onto a device wafer with a plurality of protruding patterns during packaging process. Each slot may receive the protruding patterns corresponding to two adjacent chip units of a device wafer.

This application claims the benefit of Taiwan application Serial No. 93127558, filed Sep. 10, 2004, the subject matter of which is incorporated herein by reference.

### BACKGROUND OF THE INVENTION

1. Field of the Invention

The invention relates in general to a package structure and method for electronic device, and more particularly to a package structure and method for optoelectric devices.

2. Description of the Related Art

Nowadays, the miniaturization of semiconductor components is directed towards producing a package of the same size with a semiconductor chip. The practical examples are packages such as chip scale package or chip scale package (CSP) and wafer level CSP (WLCSP). The above package structures and methods are applied in a number of optoelectric products.

For example, an image sensor micro unit package adopting a silicon wafer as a base material, according to the flip-type wafer bonding technology, covers the surface of the above silicon wafer to protect the image sensing micro unit of the silicon wafer with a transparent glass wafer to provide better optical characteristics. However, when the surface of the silicon wafer is equipped with a conductive bump or other micro units, the conductive bump and/or other micro units disposed on the silicon wafer might be damaged when the flip-type wafer is bonded on and covers up the silicon wafer due to the transparent glass wafer having a certain level of hardness.

One of the methods for resolving the above problem is to apply a soft material on the conductive bump and/or other micro unit first before the transparent glass wafer is applied. However, the above method is still inadequate when applied in a package of image sensing micro units. This is because a combined type mask formed by a soft material and a transparent glass wafer would change or even deteriorate the optical characteristics such as the transparency of the package structure.

### SUMMARY OF THE INVENTION

According to the above disclosure, the conductive bumps disposed on the silicon wafer are easily damaged by the transparent glass wafer. It is therefore an object of the invention to provide a package structure and method for micro units. A space is reserved at the part of the transparent mask corresponding to a device so that a protruding device can be received, lest the protruding device disposed on the wafer might be damaged when the flip-type wafer bonding method is applied.

Considering the optical characteristics of a combined type mask being apt to deteriorate easily, it is therefore another object of the invention to provide a package structure and method for optical micro units capable of resolving the abovementioned damage occurring to the protruding device disposed on the wafer and maintaining excellent optical characteristics with only one transparent mask.

Moreover, to avoid the complexity of the packaging process, it is therefore another object of the invention to provide a package structure and method for an image sensor package applicable to a wafer level chip scale package. Using the original sawing lines and cutting tools of the transparent wafer, a reserved space capable of receiving the protruding device of the wafer can be achieved without extra steps and tools.

The invention achieves the above-identified objects by providing a method for packaging a wafer package including the following steps: providing a silicon wafer having a first surface and a plurality of patterns projecting from the first surface, wherein the silicon wafer has a plurality of structural units; providng an optical transparent wafer having a second surface and a plurality of slots disposed under the second surface; and fixing the second wafer and the silicon wafer, wherein the second surface is fixed onto the first surface, and each of the slots receives the patterns corresponding to two adjacent structural units.

Other objects, features, and advantages of the invention will become apparent from the following detailed description of the preferred but non-limiting embodiments. The following description is made with reference to the accompanying drawings.

### BRIEF DESCRIPTION OF THE DRAWINGS

FIG. 1A is a cross-sectional diagram of a semiconductor wafer according to a first embodiment of the invention;

FIG. 1B is a cross-sectional diagram of a semiconductor wafer according to a second embodiment of the invention;

FIG. 1C is a cross-sectional diagram of an optical wafer according to the first embodiment of the invention;

FIG. 2A is a cross-sectional diagram of a wafer according to the first embodiment of the invention having completed a flip-type wafer adhering step of a packaging method; and

FIG. 2B is a cross-sectional diagram of a wafer according to the second embodiment of the invention having completed a flip-type wafer adhering step of a packaging method.

### DETAILED DESCRIPTION OF THE INVENTION

The embodiments of the invention are illustrated in accompany of drawings. During the elaboration of the embodiments of the invention, the part with respect to package structure is enlarged and explained. However, the scopes and interpretations of the invention are not to be limited thereto. Besides, in practical package structure and method, other necessary parts of the package structure should be included therein.

Next, the device or structure in the drawings of the embodiments of the invention may be exemplified by only one device or structure. However, the scopes and interpretations of the invention are not to be limited thereto, and when the number of devices or structures is not specified in the exemplification disclosed below, both the singular number and plural number are applicable according to the spirit and scope of application of the invention.

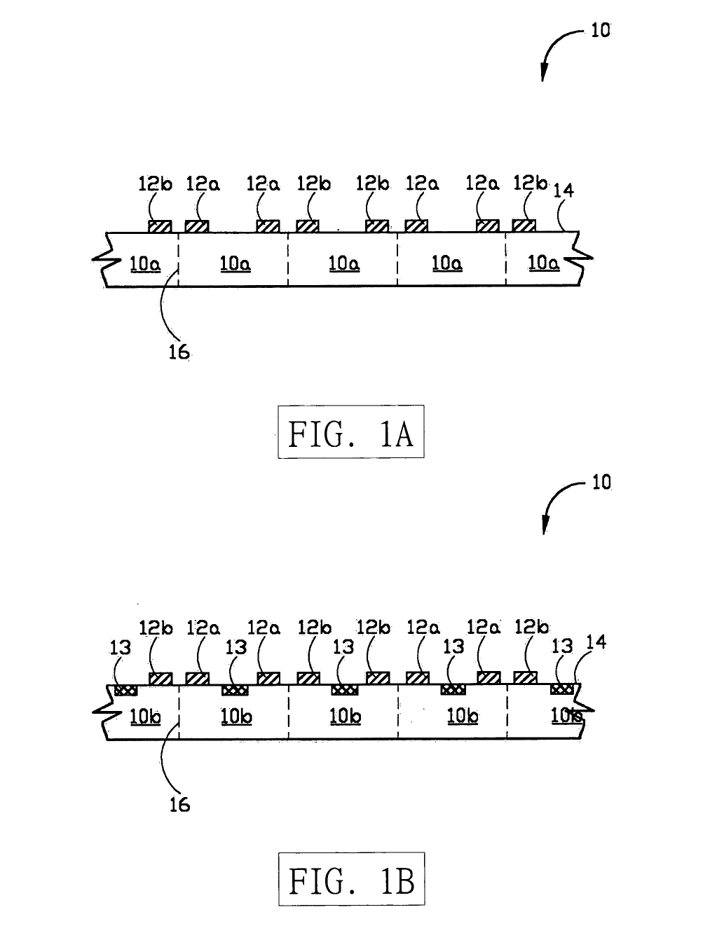

FIG. 1A is a cross-sectional diagram of a semiconductor wafer applied in a method of packaging a wafer level chip scale according to a first embodiment of the invention. Referring to FIG. 1A and FIG. 1B, semiconductor wafer 10 has one or several patterns 12a and 12b, the height on an active surface 14 (the first surface) of the semiconductor wafer 10 enables the semiconductor wafer 10 to have an uneven profile with respect to the active surface 14. Moreover, the semiconductor wafer 10 has one or several pre-determined sawing lines 16 dividing the semiconductor wafer 10 into a number of structural units 10a. While a second embodiment as shown in FIG. 1B differs from FIG. 1A in that the semiconductor wafer 10 is divided into a number of structural units 10b and may include one or several devices 13 disposed under the active surface 14.

In the first embodiment, the semiconductor wafer 10 may be a silicon wafer for instance. However, the invention is not limited to the wafer of above material. Moreover, generally speaking, whether the adjacent structural units 10a and 10b are the same or different semiconductor components is determined but not limited according to the need of design. For example, as shown in FIG. 1B, the structural unit 10b includes a device 13 such as an image sensor disposed under the active surface 14.

Next, in the first embodiment, the patterns 12a and 12b, which may be gold bumps for electrical connection or bracing or other conductive bumps but are not limited thereto, are formed on the semiconductor wafer 10 according to an ordinary method. Generally speaking, the adjacent patterns 12a and 12b have the same function and scale but correspond to different structural units. That is, the pattern 12a is corresponding to and positioned on a structural unit 10a (or 10b), and the pattern 12b is corresponding to and positioned on another structural unit 10a (or 10b). Moreover, in FIG. 1B, the pattern 12b and device 13 are not overlapped.

FIG. 1C is a cross-sectional diagram of an optical wafer applied in a flip-type wafer adhering method. Referring to FIG. 1C, with respect to a surface 24 (the second surface), one or several slots 22 are formed under the surface 24. The slots 22 are strip-shaped and may be arranged in parallel or in a matrix. In the second embodiment, isolated squared cavities (not shown in the diagram) are formed under the surface 24. Moreover, in the first embodiment, the optical wafer 20 is a glass wafer having a certain level of hardness and an excellent transparency. According to the above disclosure, the optical wafer 20 may be made of optical glass to form a homogenous mask having optical characteristics. Moreover, the optical wafer 20 has a certain level of hardness so that the patterns 12a and 12b disposed on the semiconductor wafer 10 can be maintained continuously. According to the above disclosure, the formation and material of the optical wafer 20 are not subject to any specific conditions. Any material and method of formation enabling the optical wafer 20 to achieve the above functions are within the scope of protection of the invention.

In the second embodiment, a number of sawing lines 26 are defined on the optical wafer 20 for forming the slots 22 having a reserved scale capable of receiving two adjacent patterns 12a and 12b which are adjacent to the sawing lines 16 and disposed on the semiconductor wafer 10. Therefore, the position of the sawing lines 26 on the optical wafer 20 can be determined according to the sawing lines 16 on the semiconductor wafer 10. On the other hand, the interval between two adjacent slots 22 is determined according to the size of the structural unit 10a or 10b. Moreover, the depth of each slot 22 (with respect to the surface 24), not smaller than the height of the patterns 12a and 12b, does not penetrate through the optical wafer 20.

In the second embodiment, the slots 22 corresponding to the sawing lines 16 of the semiconductor wafer 10 may be formed on the optical wafer 20 using an appropriate diffusion knife, such as a resin knife for instance, according to the sawing lines 16 on the semiconductor wafer 10. Moreover, in the second embodiment, the sawing lines 26 on the optical wafer 20 may be determined by extending the sawing line 16 disposed on the semiconductor wafer 10 along the two sides to a fixed distance. A number of parameters of cutting are set. With the sawing lines 26 and the parameters of cutting, the slots 22 in the embodiment may be formed accordingly. It is noteworthy that the selection of diffusion knife depends on the optical wafer 20 and is not limited to the resin knife disclosed in the embodiment. According to the above disclosure, the embodiment does not require a complicated positioning method when forming the slots 22 on the optical wafer 20. With the sawing lines already defined and an appropriate cutting tool, the slots 22 may be formed without adding extra steps and costs to the packaging method. Next, the slots 22 may be formed in parallel or in a matrix on the optical wafer 20, and the number of slots is determined according to the design.

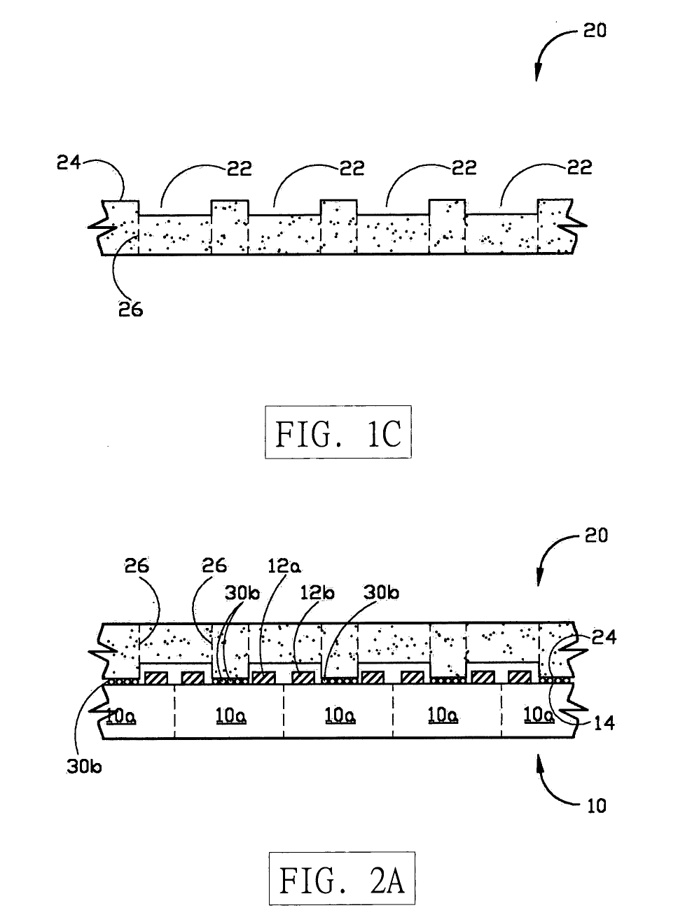

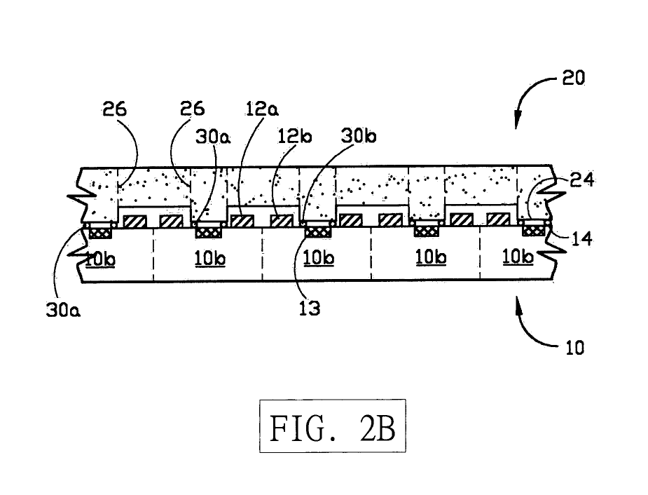

FIG. 2A and FIG. 2B are cross-sectional diagrams of a wafer having completed a flip-type wafer adhering step of a packaging method. The semiconductor wafer 10 is placed or fixed on an appropriate device. After the active surface 14 faces upwards, the optical wafer 20 is flipped for the surface 24 to face towards the active surface 14, and then the wafer may be bonded and fixed. Referring to FIG. 2A and FIG. 2B, each of the slots 22 receives the patterns 12a and 12b corresponding to different but adjacent structural units 10a or 10b. That is, the sawing lines 16 disposed on the semiconductor wafer 10 are positioned between the two adjacent sawing lines 26 defined on each of the slots 22. Moreover, the pattern 12a and 12b disposed on the two sides of each of the sawing lines 16 disposed on the semiconductor wafer 10 are positioned in the same slot 22. It is noteworthy that in the second embodiment, the adhesive structure in FIG. 2A and FIG. 2B may be formed with the optical wafer 20 being placed or fixed first and the semiconductor wafer 10 being flipped and bonded afterwards.

Moreover, a number of adhesive structures 30a and 30b, such as an adhesive mixed with spacers used for adhering and bonding two wafers and sealing the device 13 of structural unit 10b for instance, exist between the active surface 14 and the surface 24. In the present embodiment, the adhesive structures 30a and 30b disposed on the semiconductor wafer 10 or the optical wafer 20 share the same structure formed appropriately, and differ with each other only in the position of disposition. Two adjacent adhesive structures 30a are bonded and fixed on the structural unit 10b with the device 13 as shown in FIG. 2B. While the adhesive structures 30a are better not to be disposed over the sensing region of the image sensing component if the device 13 is an image sensor, the adhesive structures 30b are bonded on the structural unit 10a without the device 13 as shown in FIG. 2A. However, if the structural unit 10a has other devices, the adhesive structures 30a or 30b may be disposed on the structural unit 10a or 10b with device as long as the functions of the adhesive structures are not affected by the position of the disposition of the adhesive structure 30b.

According to the above disclosure, the space of each slot 22 is large enough to receive the patterns 12a and 12b corresponding to different structural unit 10a or 10b. A tiny clearance exists between the walls of the slot 22 and the patterns 12a and 12b, however, the present embodiment is not limited thereto. In response to the increase in integration and/or the thinning of wafer, the walls of the slot 22 may touch but not press the patterns 12a and 12b.

According to the above disclosure, the invention is applicable to the package and method using a glass/silicon or a silicon/silicon wafer for flip-type wafer bonding directly, lest the patterns on the wafer might be damaged, so that the chip can be protected and that the optical characteristics are maintained.

According to the above disclosure, a flip-type wafer structure includes a first wafer, a second wafer and a number of adhesive structures. The first wafer has a first surface and a number of patterns, and is divided into a number of structural units. The pattern are protruding from the first surface and disposed on a number of structural units. The second wafer has a second surface and a number of slots disposed under the second surface. Each slot receives the patterns disposed on two adjacent structural units. A number of adhesive structures are bonded and disposed between the first surface and the second surface.

According to the above disclosure, a method for packaging wafer level chip scale package provides a first wafer having a first surface and a number of patterns protruding from the first surface. The first wafer is equipped with a number of sawing lines to divide the first wafer into a number of structural units. Next, a second wafer is provided. The second wafer has a second surface and a number of slots disposed under the second surface. A number of adhesive structures are bonded and disposed between the first surface and the second surface. Each slot receives the patterns disposed on the two sides of each sawing line.

While the invention has been described by way of example and in terms of embodiments, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A method for packaging a wafer level chip scale package, comprising:
providing a silicon wafer having a first surface and a plurality of patterns projecting from the first surface, wherein the silicon wafer has a plurality of structural units;
providing an optical transparent wafer having a second surface and a plurality of slots disposed under the second surface; and
fixing the second wafer and the silicon wafer, wherein the second surface is fixed onto the first surface, and each of the slots receives the patterns corresponding to two adjacent structural units.

2. The method for packaging the wafer level chip scale package according to claim 1, wherein the step of providing the optical transparent wafer further comprises:
removing part of the optical transparent wafer to form the slots in the optical transparent wafer.

3. The method for packaging the wafer level chip scale package according to claim 2, further comprising forming a plurality of adhesive structures on the second surface which is between two slots.

4. The method for packaging the wafer level chip scale package according to claim 2, wherein the removing step comprises removing part of the optical transparent wafer by a knife.

5. The method for packaging the wafer level chip scale package according to claim 1, wherein the step of providing the silicon wafer further comprises:
forming a plurality of conductive bumps as being the patterns on the first surface;
forming a plurality of adhesive structures between the conductive bumps on the first surface for adhering to the second surface which is between two slots.

6. The method for packaging the wafer level chip scale package according to claim 1, wherein the step of providing the silicon wafer further comprises:
forming a plurality of gold bumps as being the patterns on the first surface; and
forming a plurality of adhesive structures between the gold bumps on the first surface for adhering to the second surface which is between two slots.
